(19) United States
(12) Patent Application Publication
(10) Pub. No.: US 2022/0240365 A1
(43) Pub. Date: Jul. 28, 2022

(54) ACTIVE THERMAL DISSIPATING SYSTEM

(71) Applicant: DTEN, Inc., San Jose, CA (US)

(72) Inventors: Wei Liu, San Jose, CA (US); Jin Guo, San Jose, CA (US); Rui Xu, San Jose, CA (US)

(21) Appl. No.: 17/572,981

(22) Filed: Jan. 11, 2022

Related U.S. Application Data
(60) Provisional application No. 63/140,438, filed on Jan. 22, 2021.

(51) Int. Cl. H05K 1/02; H05K 7/20

(52) U.S. Cl. CPC H05K 1/0203; H05K 7/20209; H05K 2201/066; H05K 7/20154; H05K 7/2039; H05K 7/20172

(57) ABSTRACT

An active temperature control system includes a thermal connection structure made of a foam layer having a light porous and semi-grid flexible material. The thermal medium is injected within closed cells and foam voids of the foam layer that couples heat dissipating layers. A cooling fan positioned adjacent to the heat dissipating layers draws heat from them.

### PRIORITY CLAIM

This application claims the benefit of priority to U.S. Provisional Application No. 63/140,438 filed Jan. 22, 2021, titled “Elastic Thermal Connection Structure,” and is related to U.S. application Ser. No. 17/______ filed Jan. 11, 2022, filed under attorney docket number 49809-20008B, titled “Elastic Thermal Connection Structure”, and U.S. application Ser. No. 17/______ filed Jan. 11, 2022, filed under attorney docket number 49809-20008D, titled “Flexible Thermal Connection Structure,” all of which are herein incorporated by reference in their entirety.

### BACKGROUND OF THE DISCLOSURE

### 1. Technical Field

This disclosure relates to heat dissipation, and in particular to active temperature management systems for electronic circuits.

### 2. Related Art

Due to the development of electronic devices, chips and circuits have become smaller and denser. As electronics are packed into smaller areas, circuit densities increase and so does heat. Heat reduces electronic device, chip, and circuit reliability and performance.

Passive thermal dissipation address this problem. In some devices, passive thermal cooling is the least expensive solution as it has few moving parts. Nonetheless, some passive thermal solutions require large dissipating areas to sustain optimum isothermal operating conditions. Because passive systems are often enclosed near the heating sources, passive thermal systems are challenging to cool.

Cooling fans are a low-cost alternative to passive thermal dissipation. The fans provide airflow in one direction. Unfortunately, cooling fans are susceptible to dust build up, bearing failure, and lubricant failure. Some cooling fans become fatigued and subject to solidification due to temperature swings and blade wear. As fatigue occurs, fan blades can become unbalanced, rotors can become misaligned, and failures increase. When cooling fans fail, forced airflow stops, circuits heat up, and performance and reliability suffers.

### BRIEF DESCRIPTION OF THE DRAWINGS

The disclosure can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is an active temperature control system.

FIG. 2 is another active temperature control system.

FIG. 3 is an active temperature control system interfacing a control system.

FIG. 4 is a process that controls an active temperature control system.

FIG. 5 is a predictive process that detects failures before they occur.

FIG. 6 is a predictive system that detects failures before they occur.

FIG. 7 is an active temperature control management system.

FIG. 8 is an active temperature control system in a teleconferencing system.

### DETAILED DESCRIPTION

An active temperature control system (aka semi-active temperature control system) compensates for the miniaturization of electronic circuits and increasing circuit densities. Using systems that passively absorb and dissipate heat and a reversible air convection, the active temperature control system maintains optimum isothermal operating ranges and consistent heat flux removal. The redundancy within the system sustains safe operating conditions and decreases the failure modes of electronic system, which is especially important in teleconferencing systems. The passive system requires a lower number of parts providing both economic benefits and safety enhancements not found in conventional systems.

Unlike reactive approaches, the predictive nature of some alternate active temperature control systems provide sufficient lead time to prevent and/or predict active temperature control failures. Some systems execute proactive functions before and/or while failures occurs such as rebalancing fan blades by adjusting bearings or rotors automatically, reducing some or all circuit or heating component power draws, and/or reducing (e.g., to reduce loading) or accelerating (e.g., to increase air velocity) shaft and blade rotational rates. Some systems provide local and/or remote notifications of predictive failures through transceivers to maintenance staff or remote locations, and/or actuate alternate cooling systems or turn-off some or all heat generating devices, circuits, or chips (referred to as chips). The remedial measures of the predictive system prevent or minimize the effects of complete circuit failures that occur at unexpected times. Identifying the likelihood of a failure keeps electronic services on-line, limits unexpected recovery time, limits unexpected expenses, minimize lost revenue and allows for preventative maintenance before chips begin to fail or completely fail.

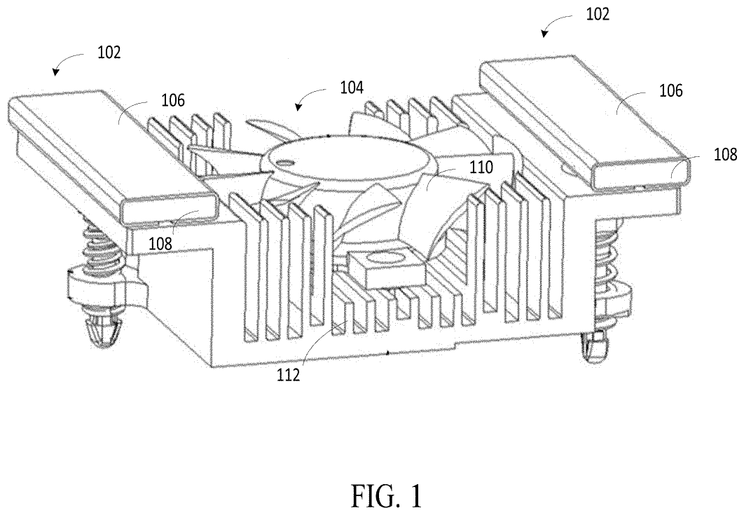

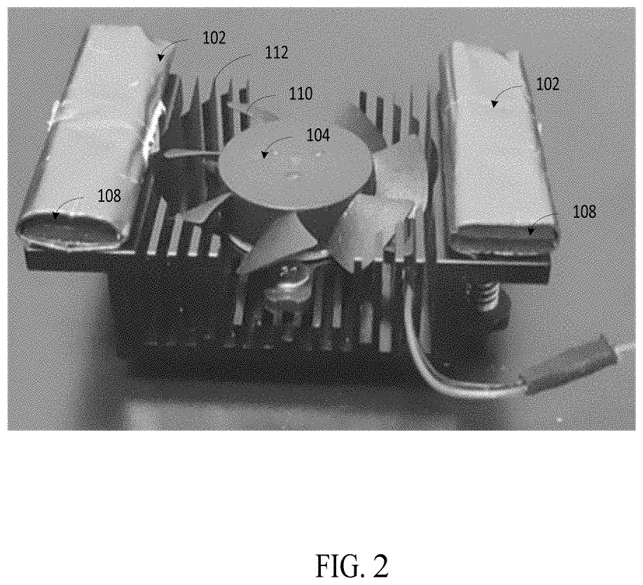

FIGS. 1 and 2 show an active temperature control system. The active temperature control system comprises systems that absorb and dissipate heat 102 and systems that circulates forced air at a constant or variable rate 104. In some temperature control systems, the systems that absorbs and dissipates heat 102 comprise an elastic thermal connection structure that includes a graphene and/or graphite sheet outer layer 106 and a foam inner layer 108. The graphite and/or graphene sheet outer layer 106 wraps and/or encloses all or some of the foam inner layer 108.

In the exemplary elastic thermal connection structure system, graphene and/or graphite and foam materials are compounded or aggregated to form a unitary elastic thermal connection with good elasticity and good thermal conductivity. An electrically and/or thermally tuned thermal convection ensure a highly efficient conductive medium with the heating components (e.g., chips, etc.) and the exposed heat dissipation elements. The system's elasticity ensure a stable, reliable, and continuous thermal connection between the electrical components and the external heat dissipation components. In cooling applications, the system's low thermal resistance ensure efficient passive heat dissipation and strong thermal conductivity to sustain a safe operating state.

Alternate systems and/or devices that absorb and dissipate heat that are part of alternate active temperature control systems comprise systems processes, and elements described in U.S. Provisional Application No. 63/140,438 filed Jan. 22, 2021, titled “Elastic Thermal Connection Structure,” and U.S. application Ser. No. 17/______ filed Jan. 11, 2022, filed under attorney docket number 49809-20008B, titled “Elastic Thermal Connection Structure”, and U.S. application Ser. No. 17/______ filed Jan. 11, 2022, filed under attorney docket number 49809-20008D, titled “Flexible Thermal Connection Structure”, all of which are incorporated by reference. Alternate active temperature control systems include any combinations of structure and functions described or shown in one or more of the FIGS. of those disclosures.

The devices that circulate air or forced air 104 include sleeve bearing fans, lube bearing fans, ball bearing fans, fluid dynamic bearing fans, magnetic levitation fans, porous bearing fans and/or other cooling elements (e.g., such as cooling tubes that circulate fluid cooled by the surrounding air) positioned near, adjacent, or between one or more elastic thermal connection structures 102. A sleeve bearing cooling fan comprises a fan having a bearing surface with no rolling elements. The bearing shaft slides directly over the bearing surface directly. Some shaft bearings have a hardened bearing surface; some include lubricant to reduce friction between the bearing surface and the shaft; some include dust penetration screens that prevent dust penetration into the bearing track. In some sleeve bearing systems, the shaft and sleeve are made of metal and the lubricant is neither thermally or electrically conductive.

The lube filled tube cooling fan used in some active temperature control systems is quieter than the ball bearing cooling fan but has a comparable lifespan. Its durability is achieved by cycling slots in the cooling fan's shaft and grooves in the bearing. When this cooling fan spins, the cycling slots in the fan's shaft circulates a lubricant and the grooves outside the bearing channel direct the lubricant's flow. In this lube filled fan, lubricant is cycled inside and outside of the tube, making the cooling fan well lubricated. The lubricants absorb and dissipate heat, absorbs vibrations, and lowers the acoustic noise level in the active temperature control systems and chips.

A ball bearing cooling fan used in some active temperature control systems includes an outer race and an inner race. The outer race passes into a bore, which receives the cooling fan's shaft. Retainers hold the ball bearings, which can be sealed and balanced with movable weights and/or adjusted by a stepper motor. The ball bearing fans includes a multi-contact area between the balls and ball-bearing races and an automatic adjusting bias that bias the ball-bearing races (e.g., via a stepper motor with a telescoping shaft that changes depth by steps and biases the races to different positions by a controller 302 to compensate of wear, unbalance or calibrate systems). The stepper motor compensates for some misalignment and/or imbalance of the fan blade that comes with wear or system failure (e.g., cooling fan failure) by adjusting the inner and/or outer ball bearing races. The disclosed ball bearing fan has a high reliability and a high precision compared to some tube-based cooling fan systems.

The fluid dynamic bearing cooling fan used in some active temperature control systems modifies a sleeve bearing by storing lubricant in its shaft when the fan is at rest (e.g., not rotating). In operation, a thin layer of lubricant separates the shaft from the bearing housing. The separation eliminates friction loses and spreads fan loads and absorbed heat across larger bearing areas. The fluid dynamic bearing cooling fan can drive high rotational speeds, at low acoustic levels while sustaining high system reliability and high fluid thermal convection that further dissipates heat.

Magnetic levitation cooling fans used in some active temperature control systems eliminates the release of gas and fluids during operation. The magnetic levitation fan rotates around a fixed orbit which is propelled by magnetic waves, which allow the fan to rotate without any or minimal friction with the bearing bore. This design minimizes temperature increases during operation be minimizing the heat generated by friction. The cooling fan can operate at very high temperatures including those exceeding two-hundred degrees Fahrenheit. The disclosed magnetic levitation cooling fan compensates for misalignments and imbalances including those caused by unbalanced shafts and/or blades by modifying the electric/magnetic fields (e.g., a variable magnetic field managed by the controller 302) transmitted by a magnetic bearing that drive the cooling fan and align and propel the shaft and fan blade.

The porous bearing cooling fan used in some active temperature control systems is similar to a solid bearing cooling fan with pores making up around 10% to 30% of the bearing stock. Under vacuum the bearing is imbued with a thermal absorbing lubricant, which is sustained by injecting lubricant into the bearing. The flowing thermal lubricant from an adjacent reservoir keeps the porous bearing lubricated when oil pressure is high and oil flows from the pores when oil pressure is low during periods of alignment or balancing. The flowing oil improves thermal dissipation of the chips and the thermal operation of the bearing.

In FIGS. 1 and 2, an exemplary cooling fan 104 comprises an electric motor and fan blades A stator positioned in a fan housing magnetically couples a rotor. The fan blades are directly coupled to the shaft of the rotor of the electric motor. A permanent magnet in the rotor fits within the housing of the rotor. Electromagnetic forces generated by the stator propels the rotor. The rotor is supported by lube bearings, two or more ball bearing, fluid dynamics bearing, magnetic levitation, porous bearings, and/or by other supporting bearings and/or parts. The disclosed bearings are not a design choice as each type of bearing and their combinations used in the active temperature control systems serve a particular result as explained by the respective properties, benefits, and functions described. Some bearing improve thermal operation, some improve thermal convection, some are adjusted in real-time in response to predicted failures, some are easy to align, some drive high rotational speeds at low acoustic levels, some dissipate heat and absorb vibrations, etc. That is each serve different functions that can be critical to maintain the performance and reliability of chip performance, operation, and reliability of an application.

In FIGS. 1 and 2, two elements comprise the active temperature control system; e.g., a device that absorbs and dissipates heat passively 102 and a device that circulates air that ensures the circulation of a variable or constant amount of air around or from heating sources and/or chips 104. Using combinations of low and/or high thermal conductivity flexible materials, the temperature control systems control the heat transfer rates thorough electronic devices. When a foam layer is used in the elastic thermal connection structure, electrical insulating and thermal conducting medium or mediums that is/are injected within the foam's closed cells and/or voids or are part of the foam itself becomes more excited as the temperature increases. As temperature increases, convection increases within the foam and between the cells and the voids, increasing the thermal convection and heat transfer flow to a heat dissipating outer layer that dissipates or exposes the heat to an open area directly or through a heat sink 112 or radiator actively cooled by the circulating air.

The one, two, or more cooling fans 104 that circulate forced air increase heat convection, which are important to systems in which passive thermal dissipation is not enough to cool chips or maintain sustainable isothermal operating ranges. As the chips reach high temperatures, the chips transfer heat to ambient air near their surfaces or near heat sinks 112 or radiators. When the air is moving near it, propelled by a cooling fan 104, the heat transfers to the air, the air rises, and cool air replaces the rising air that absorbed the heat. By moving forced air across chips, or drawing air and heat from chips, dissipating heat via elastic thermal connection structures and optional heat sinks 112 and radiators, the active temperature control systems provide a variable and/or constant source of cooler air to absorb and dissipate heat. The active temperature control systems increase and maintain a sustainable isothermal temperature operating range.

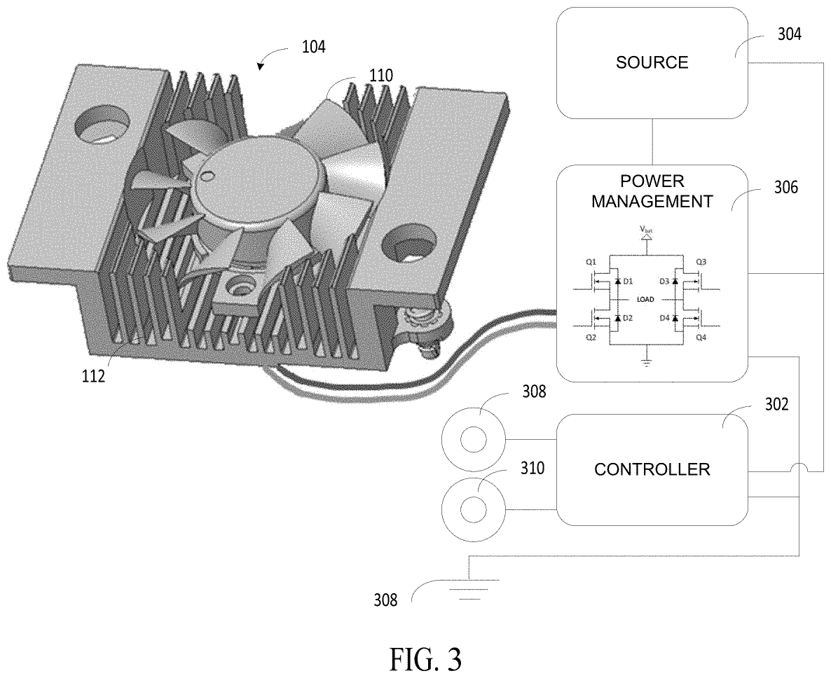

In FIG. 3, a control system or controller 302 controls the current flow thorough the stator windings for commutation. Current flow through the wound wires allows the stator to generate electromagnetic forces that drive the rotation of the rotor. A self-protected three state dual high-side circuit drives the rotor in a clockwise directions, counter clockwise direction, or a non-rotating off-state. An exemplary three state dual high-side circuit shown in the power management controller 306 implemented in an integrated circuit is shown in FIG. 3.

The top-end of a power interface of the power management controller 306 couples a source 304 (e.g., a power supply, for example) and the bottom-end of the power interface couples a ground. The load comprises the cooling fan motor that drives a shaft and fan blades 110 that circulate forced air across the heat generating components (e.g., the chips) and passive systems 102 to increase heat convection and dissipation.

In operation, when Q1 and Q4 are turned on and Q2 and Q3 are turned off, the top lead of the fan motor (shown in red) couples the positive lead of power supply, while the bottom lead (shown in black) couples ground. In this state, current flows through the motor which energizes the motor in a forward direction or a clockwise direction. With Q1 and Q4 turned off and Q2 and Q3 are turned on, current flows in the reverse direction causing the motor to energize in a reverse direction, or a counter clockwise direction. That is when Q2 and Q3 are turned on and Q1 and Q4 are turned off, the bottom lead of the fan motor (shown in black) couples the positive lead of the power supply, while the bottom lead (shown in red) couples ground. When Q1-Q4 or both Q1 and Q3 or both Q2 and Q4 (assuming Q1 and Q3 are matched) are turned off, the motor remains in or enters an off or wait state. To prevent a shoot through state, the controller ensures both Q1 and Q2 (or Q3 and Q4) are never turned on at the same time. In a shoot through state, the power management circuit provide a low resistance path to ground, effectively short circuiting the source 304.

In FIG. 3, the controller 302 monitors, the source output 304, the ground plane 308, and/or processes the temperature of the chips of electronic device and external temperatures remote from the electronic device (or chips). While multiple temperature sensors 308 and 310 are shown, in some systems a single temperature sensor is used. In some systems, an infrared (IR) sensor measures internal surface temperature of the chips and external temperatures remote from but in proximity to the electronic device. In the IR sensor, infrared energy is focused on a surface where it measures how much IR is reflected and/or absorbed. The IR sensors use one or more lenses to focus the infrared energy on an object and measures it. The sensors 308 and 310 absorb the reflected infrared radiation and converts it into electrical signals that are referenced to temperature readings. The stronger the radiation the sensor receives the stronger the electrical signal becomes. The IR sensor or the controller 302 calibrates the electrical signal to temperature readings that are further processed by the controller 302. In some systems, other sensors are used such thermal infrared sensors (TIRS), thermocouple sensors, etc.

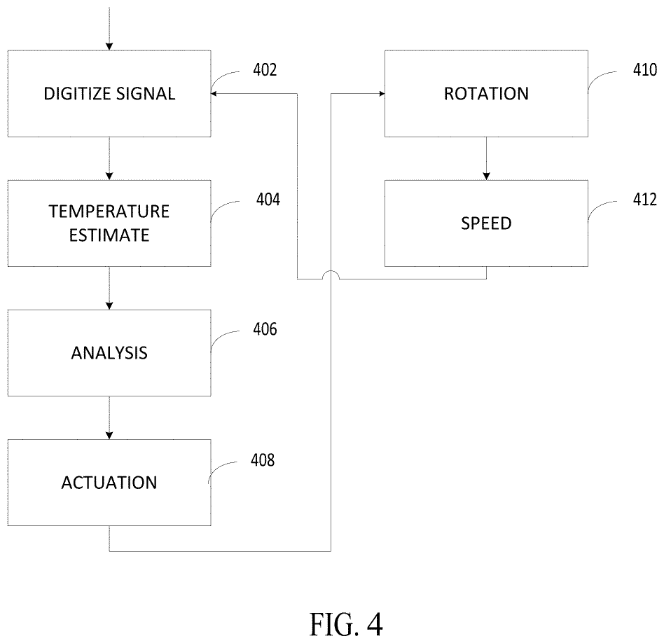

In some active temperature control systems, the controller 302 converts continuously varying (analog) signals, such as current or voltage generated by sensors 308 and 310 into digital data that is translated into temperature estimates at 402 and 404 of FIG. 4. The temperatures estimate the ambient air and the external air temperature remote from the chips and electronic device that can be drawn in when needed (e.g., if the external air is cooler than the ambient air that is near the chips). Based on the controller's analysis at 406 of ambient and external temperatures, a desired airflow rate (e.g., m³/sec) is calculated to sustain a desired isothermal temperature operating range and an airflow flow direction (e.g., drawing cooler air toward the chips or drawing warmer air away from the chips or a combination depending on the conditions) at 408 is established, which changes in real time. A real time system updates and/or modifies fan operation as to receives information, enabling the direct control of the system such as an automatic pilot.

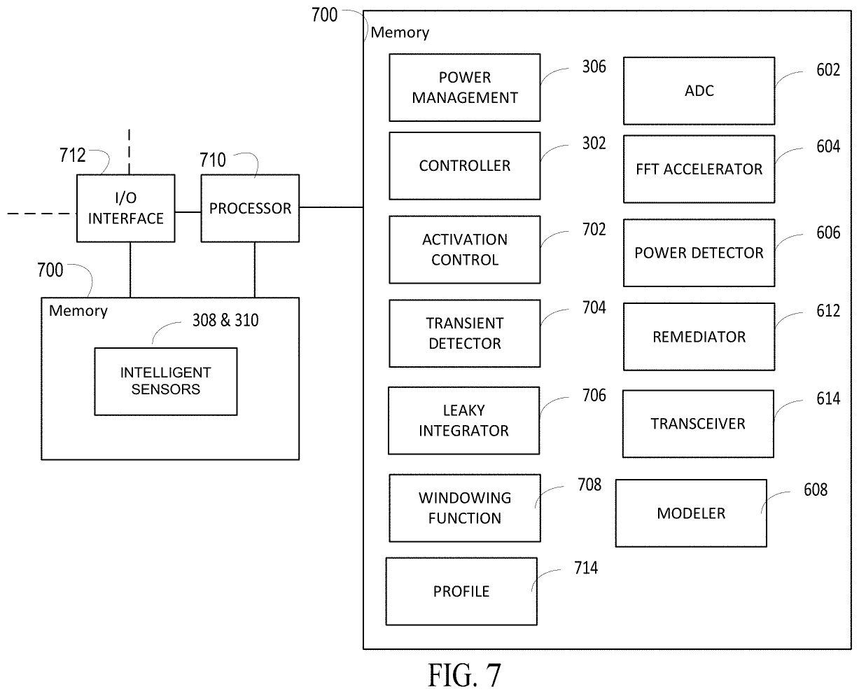

The controller 302 determines the cooling fans to activate (when system includes more than one cooling fan), the direction of the fan blade rotations, respectively, (e.g., a clockwise rotation draws external air toward the chips and counterclockwise rotation draws a local warm ambient airflow away from the chips) at 410 (including a reversing a current fan blade rotation), and the respective speeds the fans operate such as one, two, three, four or more predetermined speeds (e.g., V₀, V₁, V₂, V₃, V₄, . . . etc.) at 412, the fan blades spin at to sustain a desired isothermal temperature range by accessing activation control parameters 702 stored in a memory 700 (shown in FIG. 7). The selected actuation, direction, and speed is controlled by current flow including the amount and direction of current flow sourced through the stators established by the controller 302 and activation control parameters 702, respectively, in some systems, in other systems, rotor or fan blade speed is determined by the controller's 302 selection of the respective cooling fans' windings (e.g., that may include a separate low speed stator winding, a separate intermediate speed stator winding, and/or a separate high speed stator winding or a combination, respectively) by referencing the activation control parameters 702.

Some alternate active temperature control systems predict and detect active temperature control failures in real time (analyzing data as fast or substantially as fast as the rate it is received). Some systems detect pre-failure conditions and provide sufficient lead time to prevent system failures. The systems identify signals across a low frequency band (e.g., the power band) including reoccurring signals that gradually increase in amplitude before gradual tapering off. While some reoccurring signals or transient spikes may be nearly identical, others are not and do not have nearly identical spectral structures.

In some systems, transient event detectors 704 (shown in FIG. 7) identify pre-failure conditions that are shown by transient events included reoccurring transient events based on spectral and temporal structures that are detected at the source 304 and/or ground plane 308. A transient is temporary in nature and exists for a short duration (usually hundredths n seconds). They often originate from switching or other causes such as when systems experience unstable conditions.

Using a weighted average, or other modeling techniques like a leaky integrator 706, a transient event detector 704 also estimates the temporal spacing between transient signals including the reoccurring transient signals. When the transient detector 704 identifies a transient and/or reoccurring transient event, the transient detector 704 analyzes the input forward and/or backward in time to identify a similar signal having substantially the same or nearly similar characteristics that are modeled in a failure profile 714 stored in a memory 700. In some systems, transient signals are identified based on the degree or threshold to which the signal is linearly related to a known transient signal or a condition that precedes it (e.g., a pre-failure condition or unstable condition) that is pre-modeled and associated with a failure condition in the profile 714. The degree of similarity or threshold levels may vary with other events including the presence of other sudden ephemeral surging signals and/or attenuated signals or voltages.

Using a sampling window 708, the controller 302 measures signals at the source 304 and/or signals on the ground plane 308 to calculate source and/or ground signal mean failure conditions or unstable conditions during intervals that model failure events including those associated with reoccurring transient events and/or those that precede temperature control system failures within a predetermined time such as intervals that occur thirty minutes before a failure, intervals that occur twenty minutes before a failure, intervals that occur five minutes, intervals that occur less than five minutes, etc. before a failure, etc. or those that occur during active temperature control system failures, and/or following active temperature control system failures. In the frequency domain, a weighted average may model transient conditions (e.g., to generate a classification model and/or a regression model) including the conditions and characteristics that immediately precede failure events which include reoccurring transient signals and the time between them and also includes the normal operating state conditions for each frequency bin, in other systems.

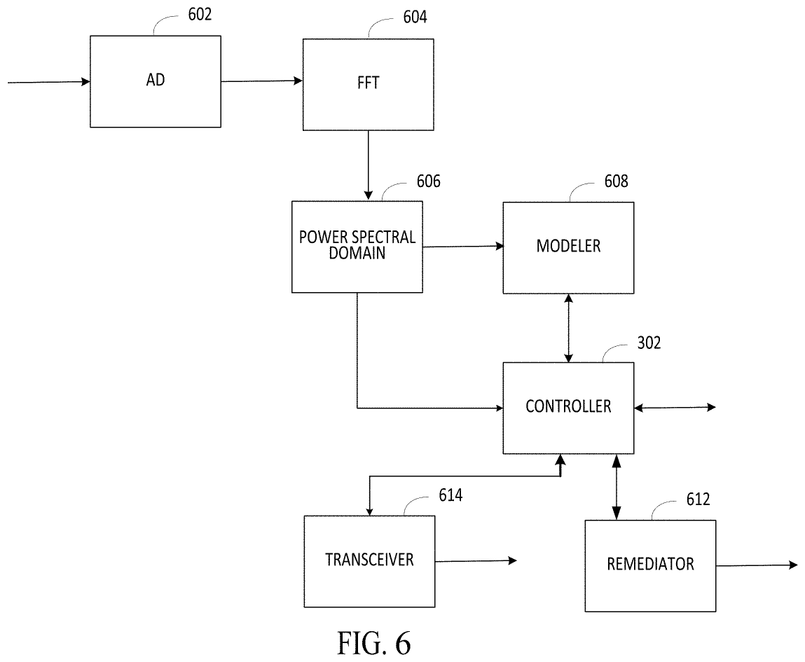

The models are generated, updated, and averaged by a modeler 608 (shown in FIGS. 6 and 7) so that the models reflect the operating state of the temperature control systems of the system contemporaneously or in real time. Alternatively, the models may be updated each time a cooling fan and/or other active cooling elements or component is activated. Because the models generated by the active temperature control systems train on real operational data generated during the times that occur well before a device failure (e.g., normal operating periods) and those that just precede failures (e.g., within conditioned pre-failure periods), the temperature control systems protect against known and unknown causes of device failures. The systems do not need to detect, identify, or know the source or originating causes or sources of a device's failure to predict the active temperature system's failure and prevent it. The active temperature control systems are different from other systems that recognize known device failures or causes, typically by comparing only data generated during those failures (i.e., during the time the failures are occurring) against failure data. The disclosed active operating approach and active temperature control systems analyze one or more data continuously or periodically data to determine if one or more active temperature control devices will be in a state that precede a failure.

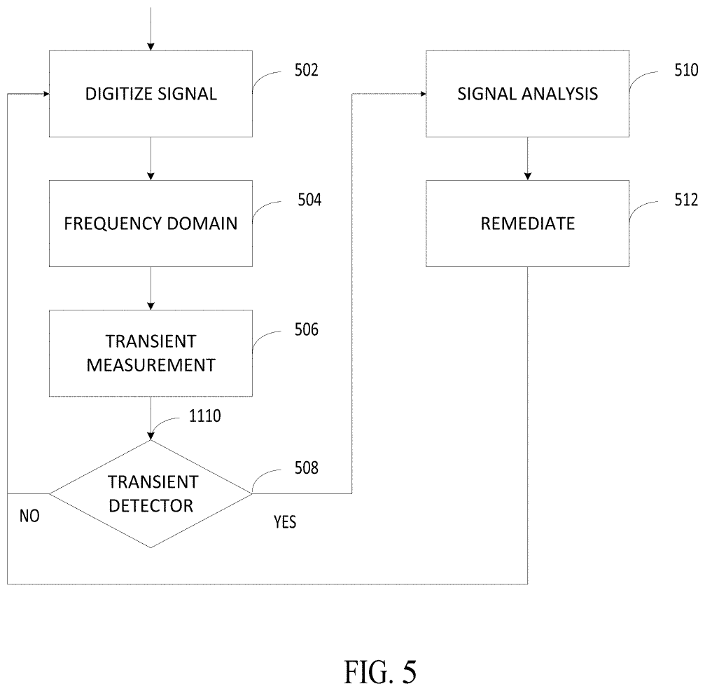

FIG. 5 is a predictive process that detects failure conditions that precede failures, occur during failures, and follow failures of active temperature control systems. A temporal frequency converter (comprising an analog-to-digital converter 602, and a digital Fast-Fourier-Transform shown as an FFT accelerator 604 in FIGS. 6 and 7) converts a windowed continuously varying analog signal from the source and/or ground into the frequency domain at 502 and 504. A steady state estimator that comprises a power detector 606 averages the power in each frequency bin in the power or magnitude domain that includes phase in some systems at 506. The steady state estimator is disabled during abnormal increases in power conditions in some systems.

To detect pre-failure events, failure events, and monitor post event failures the transient event detector 704 corresponds the estimated or measured signals to the modeled conditions generated by a modeler 608 that immediately precede a failure and/or identify operating conditions that occur during a temperature control system's failure at 508. In some systems, the degree to which the estimated frequency bins correspond to pre-failure and/or failure model frequency bins may be represented by a correlation coefficient, with a value of zero indicating no correlation, a negative one indicating a perfect negative correlation, and a positive one indicating a perfect positive condition at 508. Alternatively or additionally, the system may determine a probability that the signal comprises a transient signal corresponding to a pre-failure and/or failure condition. The indication occurs when the probability exceeds a predetermined probability threshold in some systems at 508. The probability thresholds and/or correlation coefficients that identify the conditions depend on the electronic devices safe operating condition ranges that may reflect loading/signals on the source, loading/signals on the ground plane, and/or other characteristics.

At 510, the controller 302 (via its analysis) mark the pre-failure conditions, failure conditions, and/or post failure conditions which causes or initiates the controller 302 to execute proactive functions before failures occurs or as they occur at 512 such as automatically rebalancing fan blades (e.g., modifying bearings by adjusting races in some ball bearing fans, adjusting magnetic fields in magnetic levitation bearings, etc.), or rotors automatically, reducing power draws (e.g., power down circuits), and/or reducing or accelerating rotational rates, which reduce loading or increase air flow rates of other active components via a remediator 612. Some systems, alternatively or additionally, provide local and/or remote continuous or periodic notifications to remote destinations via a transceiver 614, and/or actuate alternate cooling systems or turn-off some or all heat generating devices, circuits, or chips (referred to as chips). The notifications identifies the likelihood of one or more potential failures, where the potential failures are likely to occur, and/or in some systems, when the potential failures will occur and/or the time-to-failure and/or how long the failures are expected to last. The systems provide more timely predictions with fewer false positive predictions than known predictive systems that predict failure conditions through the system's learning processes.

FIG. 7 is a block diagram of an alternate active temperature control system that may execute the process flows and characteristics described above and those shown in FIGS. 1-6 and 8. The system comprises a processor 710, a non-transitory media such as a memory 700 (the contents of which are accessible by the processor 710), and an I/O interface 712. The I/O interface 712 connects devices and local and/or remote applications such as, for example, additional local and/or remote monitored devices. The memory 700 stores instructions, which when executed by the processor 710, causes the active temperature control system to render some or all of the functionality associated with managing temperatures and predicting system events such as a device failure, for example. The memory 700 stores instructions, which when executed by the processor 710, causes the active temperature control system to render functionality associated with the power management 306, controller 302, activation controls 702, transient detector 704, leaky integrator 706, windowing function 708, analog-to-digital converter 602, FFT accelerator 604, power detector 606, remediator 612, transceiver 614, profile 714, and modeler 608. In yet another alternate active temperature control system, the non-transitory media provided functionality is provided through cloud storage. In this active temperature control system, cloud storage provides ubiquitous access to the active temperature control system's resources and higher-level services that can be rapidly provisioned over a network. Cloud storage allows for the sharing of resources to achieve coherence services across many monitored devices at many locations and provides economies of scale.

The memory 700 and/or storage disclosed may retain an ordered listing of executable instructions for implementing the functions described above in a non-transitory computer code. The machine-readable medium may selectively be, but not limited to, an electronic, a magnetic, an optical, an electromagnetic, an infrared, or a semiconductor medium. A non-exhaustive list of examples of a machine-readable medium includes: a portable magnetic or optical disk, a volatile memory, such as a Random Access Memory (RAM), a Read-Only Memory (ROM), an Erasable Programmable Read-Only Memory (EPROM or Flash memory), or a database management system. The memory 700 may comprise a single device or multiple devices that may be disposed on one or more dedicated memory devices or disposed on a processor or other similar device. An “controller” may comprise a processor (hardware) and/or a portion of a program that executes or supports temperature control and/or failure predictions or processes. When functions, steps, etc. are said to be “responsive to” or occur “in response to” another function or step, etc., the functions or steps necessarily occur as a result of another function or step, etc. It is not sufficient that a function or act merely follow or occur subsequent to another. Further, the term “failure” generally refers to a system or related device that does not operate reliably, operates in an unstable state, and/or does not operate at all. A “failure” may be caused by software or hardware. The term “substantially” or “about” encompasses a range that is largely (ninety five percent or more), but not necessarily wholly, that which is specified. It encompasses all but an insignificant amount such as within five percent and includes its limits in some systems. The term “near” means within a short distance (e.g., conventionally measured in centimeters) or interval in space or time.

When an event threshold is set to a very high level, such as about a ninety percent probability event threshold, for example, some active temperature control systems are very accurate (e.g., it renders few false positive events) and are very effective. Nearly all of the failures are preceded by a prediction. At an even higher event threshold level of nearly ninety-five percent, all but one predicted crash is preceded by a failure in some systems.

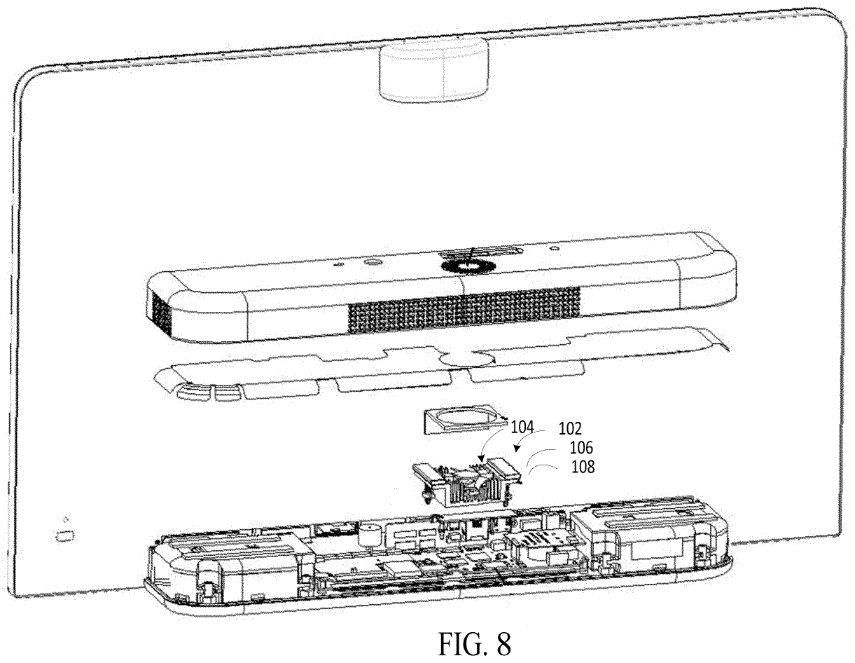

While each of the systems and methods shown and described herein operate automatically and operate independently, they also may be encompassed within other systems and methods such as the teleconferencing system shown in FIG. 8 and used to recognize a failure or any other type of unstable condition. A teleconferencing system uses audio, video, and/or computer equipment linked through a communication system to enable geographically separate individuals usually to participate in meeting or discussions. A meeting session supported by the system include video images that are transmitted to various geographically separate locations. Typically, the images comprise digital images transmitted over a wider area network or the Internet and include input and displays from application programs in real time.

Alternate active temperature control systems include any combinations of structure and functions described or shown in one or more of the FIGS. These active temperature control systems and methods are formed from any combination of structures and functions described including those incorporated by reference. The structures and functions may process additional or different input.

The functions, acts or tasks illustrated or described in the FIGS. may be executed in response to one or more sets of logic or instructions stored in or on non-transitory computer readable media as well. The functions, acts or tasks are independent of the particular type of instructions set, storage media, processor or processing strategy and may be performed by software, hardware, integrated circuits, firmware, micro code and the like, operating alone or in combination.

The active temperature control systems compensates for the miniaturization of electronic circuits and increasing circuit densities. Using systems that absorb and dissipate heat passively and a reversible air convection, the active temperature control system maintains optimum isothermal operating ranges and consistent heat flux removal. The redundancy within the system sustains safe operating conditions and decreases the failure modes of electronic system, which is especially important in teleconferencing systems. The passive system requires a lower number of parts providing both economic benefits and safety enhancements not found in conventional systems

The active temperature control system improves the reliability of electronic devices by detecting operating conditions that precede failures. The systems and methods provide predictions with sufficient lead-times to mitigate failures. Some systems execute proactive functions before and/or while failures occurs such as rebalancing fan blades by adjusting bearings, repositioning shafts or rotors automatically, reducing power draws, and/or reducing or accelerating shaft and blade rotational rates in response to the detection and the controller 302. Some systems provide local and/or remote notifications to destinations, users, networks, and/or sites through transceivers, and/or actuate alternate cooling systems or turn-off some or all heat generating devices, circuits, or chips (referred to as chips). The remedial measures of the predictive system prevent or minimize the effects of complete circuit failures that occur at unexpected times. Identifying the likelihood of a failure keeps electronic services on-line, limits unexpected recovery time, limits unexpected expenses, minimize lost revenue and allows for preventative maintenance before chips fail or completely fail.

Because the pre-failure and failure models generated by the active temperature control systems train on data generated during the times that occur well before a device failure (e.g., during a normal operating period) and those that precede and follow failures, the active temperature control systems protect against known and unknown causes of device failures and adapts to the system's operating state. The systems do not need to detect or identify the originating causes of a device's failure to predict a failure and prevent it.

Other systems, methods, features and advantages will be, or will become, apparent to one with skill in the art upon examination of the figures and detailed description. It is intended that all such additional systems, methods, features and advantages be included within this description, be within the scope of the disclosure, and be protected by the following claims.

What is claimed is:

1. An active temperature control system, comprising:
a foam layer comprising a light porous, semi-grid flexible material;
a thermal conducting medium injected within closed cells and voids of the foam layer;
a plurality of heat dissipating layer that couples the thermal conducting medium comprising a ring that has thermal conductivity of at least 1.3 W m⁻¹ K⁻¹; and
a cooling fan positioned adjacent to the plurality of heat dissipating layers that draws heat from the plurality of heat dissipating layers.

2. The temperature control system of claim 1 where the heat dissipating layer encloses the thermal conducting medium.

3. The temperature control system of claim 2 where the heat dissipating layer couples a heat sink.

4. The temperature control system of claim 3 where the cooling fan comprises a magnetic bearing that compensates for fan blade imbalances by varying a magnetic field.

5. The temperature control system of claim 2, where a mean foam pore size lies at or between about 100-200 μm and comprises a density of about 5 mg⁻³.

6. The temperature control system of claim 5 where the cooling fan comprises a telescoping shaft coupled to a ball-bearing race.

7. The temperature control system of claim 3 further comprising a controller that modifies a direction of air flow by a reversing of a current fan blade rotation based on an ambient air temperature of an electronic device and a remote air temperature in proximity to the electronic device.

8. The temperature control system of claim 7 where the controller establishes a fan blade speed by selecting a separate stator winding from a plurality of windings.

9. The temperature control system of claim 7 further including a transient detector that identify a pre-failure condition based on spectral and temporal structures at a source.

10. The temperature control system of claim 7 further including a transient detector that identify a pre-failure condition based on spectral and temporal structures on a ground plane.

11. The temperature control system of claim 10 further comprising a leaky integrator that estimates a temporal spacing between a plurality of transient signals.

12. The temperature control system of claim 10 further comprising a controller that calculates a circuit ground mean unstable condition that precedes a failure condition.

13. The temperature control system of claim 12 further comprising a modeler that updates the conditions and characteristics that immediately precede a cooling fan failure.

14. The temperature control system of claim 13 where the updates occur in real time.

15. The temperature control system of claim 1 further comprising a temporal frequency converter that converts a windowed continuously vary analog signal.

16. The temperature control system of claim 15 further comprising a power detector that averages the power in a plurality of frequency bins generated by the temporal frequency converter.

17. The temperature control system of claim 16 further comprising a transient event detector that identifies a pre-failure condition by comparing a transient condition to a pre-failure modeled condition.

18. The temperature control system of claim 17 further comprising a controller that marks pre-failure conditions.

19. The temperature control system of claim 18 where the controller initiates a proactive function.

20. The temperature control system of claim 19 where the proactive function comprises automatically rebalancing a plurality of fan blades of the cooling fan.
